(19) United States
(12) Patent Application Publication
(10) Pub. No.: US 2024/0212995 A1
(43) Pub. Date: Jun. 27, 2024

(54) APPARATUS FOR TREATING SUBSTRATE

(71) Applicant: SEMES CO., LTD., Cheonan-si (KR)

(72) Inventors: Yoon Seok CHOI, Suwon-si (KR); Yun Sang KIM, Seongnam-si (KR); Sang Jeong LEE, Hwaseong-si (KR); Jae Won SHIN, Suwon-si (KR); Jong Won PARK, Yongin-si (KR)

(73) Assignee: SEMES CO., LTD., Cheonan-si (KR)

(21) Appl. No.: 18/390,078

(22) Filed: Dec. 20, 2023

(30) Foreign Application Priority Data
Dec. 22, 2022 (KR) 10-2022-0181645

(51) Int. Cl. H01J 37/32

(52) U.S. Cl. CPC H01J 37/32697; H01J 37/32522; H01J 37/32541; H01J 37/3255; H01J 37/32724; H01J 2237/2007

(57) ABSTRACT

The inventive concept provides a substrate treating apparatus. The substrate treating apparatus includes a chamber having a treating space; a support unit configured to support a substrate in the treating space; a window plate positioned above the treating space; and a conductive layer formed on the window plate, and wherein a bottom surface of the window plate is exposed to the treating space, and the conductive layer is formed on a top surface among a top surface and a bottom surface of the window plate.

### CROSS-REFERENCE TO RELATED APPLICATIONS

A claim for priority under 35 U.S.C. § 119 is made to Korean Patent Application No. 10-2022-0181645 filed on Dec. 22, 2022, in the Korean Intellectual Property Office, the entire contents of which are hereby incorporated by reference.

### BACKGROUND

Embodiments of the inventive concept described herein relate to a substrate treating apparatus, more specifically, a substrate treating apparatus for treating a substrate using a plasma.

A plasma refers to an ionized gas state consisting of ions, radicals, and electrons. The plasma is generated by a very high temperature, a strong electric field, or an RF Electromagnetic Field. The plasma and substrates such as a wafer interact with each other to perform various semiconductor element manufacturing processes such as an etching process.

FIG. 1 is a cross-sectional view schematically showing a general substrate treating apparatus. Referring to FIG. 1, the substrate treating apparatus 1000 includes a process chamber 1100, a support unit 1200, a gas supply unit 1300, a top electrode unit 1400, and a heat source 1500. The process chamber 1100 has a treating space in which the substrate W is treated. The support unit 1200 supports the substrate W in the treating space. In addition, the support unit 1200 is grounded and functions as a bottom electrode. The gas supply unit 1300 supplies a gas excited by the plasma to the treating space. The top electrode unit 1400 includes a window plate 1420 capable of transmitting a light or microwaves. A high frequency power is applied to the window plate 1420 to function as a top electrode. The heat source 1500 transmits a heat source such as a light or microwaves to the window plate 1420. The window plate 1420 may be provided with a conductive layer 1440 and if the conductive layer 1440 is exposed to the treating space, it is degraded by the plasma generated in the treating space. If the conductive layer 1440 is degraded, a function of the top electrode is degraded, and characteristics of the electric field formed in the treating space are changed, making it difficult to generate a uniform plasma in the treating space. In addition, if the conductive layer 1440 is degraded, particles are generated in the window plate 1420, and the generated particles are attached to the substrate W, causing problems in a process yield.

### SUMMARY

Embodiments of the inventive concept provide a substrate treating apparatus for solving the above-mentioned problems.

Embodiments of the inventive concept provide a substrate treating apparatus for generating a uniform plasma according to a recipe.

Embodiments of the inventive concept provide a substrate treating apparatus for minimizing a damage caused by a plasma on a conductive layer.

Embodiments of the inventive concept provide a substrate treating apparatus for effectively transmitting a heat source to a treating space.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chamber having a treating space; a support unit configured to support a substrate in the treating space; a window plate positioned above the treating space; and a conductive layer formed on the window plate, and wherein a bottom surface of the window plate is exposed to the treating space, and the conductive layer is formed on a top surface among a top surface and a bottom surface of the window plate.

In an embodiment, the conductive layer is coated to have a predetermined thickness on the top surface of the window plate.

In an embodiment, an electrode in a ring shape to which a high-frequency voltage is applied is disposed above the conductive layer.

In an embodiment, the electrode is positioned within a coated region of the conductive layer when seen from above.

In an embodiment, the electrode is disposed along a circumference of an edge region of the conductive layer.

In an embodiment, the electrode partially overlaps a substrate supported on the support unit when seen from above.

In an embodiment, a bottom surface of the electrode and a top surface of the conductive layer are bonded to each other by an ohmic contact.

In an embodiment, a material of the window plate includes a quartz, a material of the electrode includes a metal, and the metal includes a copper (Cu) or an aluminum (Al).

In an embodiment, the conductive layer is provided as a transparent conductive layer, and the transparent conductive layer is made of a material including an ITO (Indium tin oxide).

In an embodiment, the substrate treating apparatus further includes: a heating unit configured to transfer a heat source to a substrate supported on the support unit, and wherein the heating unit is positioned at a top side of the transparent conductive layer.

In an embodiment, the heating unit transfers the heat source to the treating space by passing through the transparent conductive layer.

In an embodiment, the heating unit includes a lamp, a laser optical system, or a microwave generator.

The inventive concept provides a substrate treating apparatus. The substrate treating apparatus includes a window plate dividing into an outer space at a top side and a treating space at a bottom side; an electrode positioned at the outer space and forming an electric field at the treating space by applying a power; a heating unit positioned at the outer space and configured to transfer a heat source to the treating space; and a transparent conductive layer positioned at the outer space among the treating space and the outer space.

In an embodiment, the electrode is disposed along a circumference of an edge region of the transparent conductive layer.

In an embodiment, the electrode is positioned above the edge region of the transparent conductive layer.

In an embodiment, the transparent conductive layer is formed at a top surface of the window plate, and the heating unit transfers the heat source toward the transparent conductive layer.

In an embodiment, the electrode partially overlaps with a substrate positioned at the treating space when seen from above.

In an embodiment, a bottom surface of the electrode and a top surface of the transparent conductive layer are bonded to each other by an ohmic contact.

In an embodiment, a material of the window plate includes a quartz, a material of the electrode includes a copper (Cu) or an aluminum (Au), and the transparent conductive layer is made of material including an ITO (Indium tin oxide).

The inventive concept provides a substrate treating apparatus. The substrate treating apparatus includes a chamber having a treating space; a support unit configured to support a substrate in the treating space; a gas supply unit configured to supply a gas to the treating space; an electrode positioned outside of the treating space, and exciting a gas supplied to the treating space by applying a high-frequency voltage; a heating unit positioned outside of the treating space and configured to transmit a heat source to the treating space; a window plate with its bottom surface exposed to the treating space and its top surface positioned outside of the treating space; and a transparent conductive layer formed on the top surface of the window plate, and wherein a top surface of the transparent conductive layer and a bottom surface of the electrode contact each other, the heating unit is positioned at a top side of the transparent conductive layer, the electrode is positioned at an edge region of the transparent conductive layer along a circumferential direction of the transparent conductive layer, the heating unit transmits the heat source to the treating space by passing through the transparent conductive layer, a material of the electrode includes a copper (Cu) or an aluminum (Al), and the transparent conductive layer is made of a material including an ITO (Indium tin oxide).

According to an embodiment of the inventive concept, a substrate may be efficiently treated.

According to an embodiment of the inventive concept, a uniform plasma according to a recipe may be generated.

According to an embodiment of the inventive concept, a damage caused by a plasma on a conductive layer may be minimized.

According to an embodiment of the inventive concept, a heat source may be efficiently transmitted to a treating space.

According to an embodiment of the inventive concept, an energy loss by an ion may be minimized to generated a high-density plasma.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view schematically showing a general substrate treating apparatus.

FIG. 2 is a cross-sectional view schematically illustrating the substrate treating apparatus according to an embodiment.

FIG. 3 is a perspective view schematically illustrating a window plate and an electrode according to an embodiment.

FIG. 4 schematically illustrates the window plate and the electrode viewed from above according to an embodiment.

FIG. 5 is a graph schematically illustrating a trend of a sheath voltage in the substrate treating apparatus according to an embodiment.

FIG. 6 is a graph schematically illustrating a trend of a density of a plasma generated in the substrate treating apparatus according to an embodiment.

FIG. 7 is a cross-sectional view schematically illustrating the substrate treating apparatus according to another embodiment.

FIG. 8 schematically illustrates a substrate being treated in the substrate treating apparatus of FIG. 7.

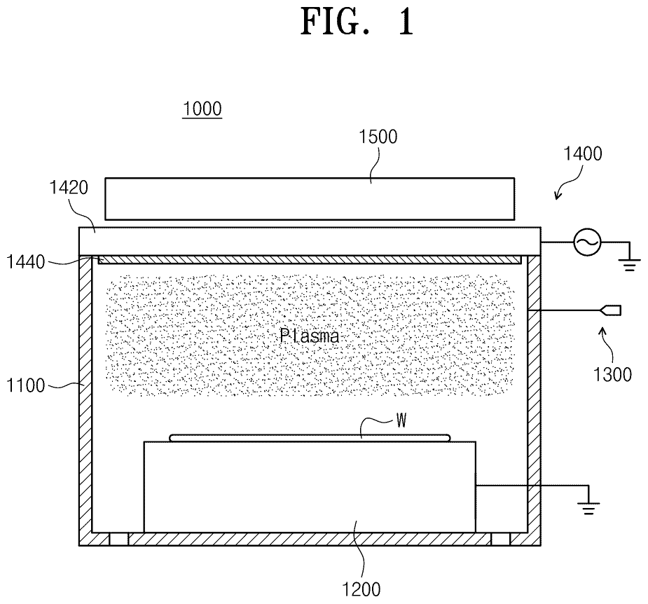

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

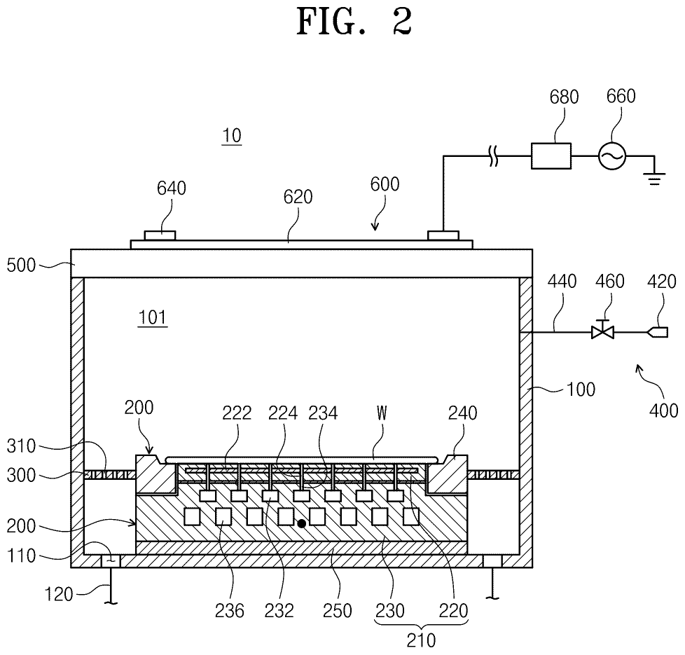

FIG. 2 is a cross-sectional view schematically illustrating a substrate treating apparatus according to an embodiment.

The substrate treating apparatus 10 according to an embodiment treats a substrate W using a plasma. For example, the substrate treating apparatus 10 can perform an etching process to remove a thin film formed on the substrate W using the plasma, an ashing process to remove a photoresist film, a deposition process to form the thin film on the substrate W, an ALD (Atomic Layer Deposition) process to deposit an atomic layer on the substrate W, an ALE (Atomic Layer Etching) process to etch the atomic layer on the substrate, or a dry-cleaning process to remove a foreign substrate attached to the substrate, etc. In addition, the substrate treating apparatus 10 can perform a surface modification process of modifying a surface of the substrate W using the plasma. However, it is not limited to the above-described example, and the substrate treating apparatus 10 may be applied equally or similarly to various apparatuses which process the substrate W such as a wafer using the plasma.

The substrate treating apparatus 10 may include a chamber 100, a support unit 200, a gas supply unit 400, a window plate 500, and an electrode unit 600.

The chamber 100 has a treating space 101 therein. The treating space 101 functions as a space for treating the substrate W. In addition, the treating space 101 may be a space in which the plasma is generated. An opening (not shown) through which the substrate W is taken in and out is formed on a sidewall of the chamber 100. The opening (not shown) may be selectively opened and closed by a door assembly not shown. An inner sidewall of the chamber 100 may be coated with a material capable of preventing an etching by a plasma generated in the treating space 101. In addition, the chamber 100 may be grounded.

An exhaust hole 110 is formed at a bottom of the chamber 100. The exhaust hole 110 connects to an exhaust line 120. A pump which is not shown may be installed in the exhaust line 120. The pump (not shown) regulates a pressure of the treating space 101 by applying a negative pressure to the exhaust line 120 and exhausting an atmosphere of the treating space 101. In addition, the pump (not shown) discharges foreign substances remaining in the treating space 101 to the outside of the treating space 101. The pump (not shown) according to an embodiment may be any one of known pumps applying the negative pressure.

The support unit 200 is positioned in the treating space 101. The support unit 200 is disposed to face the window plate 500 at a bottom side of the window plate 500 to be described later. The support unit 200 supports the substrate W. Unlike FIG. 2, the support unit 200 may be positioned to be spaced apart from a bottom of the chamber 100 by a predetermined distance in an upward direction. For example, it may be positioned to be spaced apart from the bottom of the chamber 100 through a connection unit (not shown) connected to the sidewall of the chamber 100. The support unit 200 according to an embodiment may include an electrostatic chuck which chucks the substrate W using an electrostatic force. Alternatively, the support unit 200 may support the substrate W in various ways such as a vacuum adsorption or a mechanical clamping. Hereinafter, the support unit 200 including the electrostatic chuck will be described as an example.

The support unit 200 may include an electrostatic chuck 210 and an insulating plate 250.

The electrostatic chuck 210 may include a dielectric plate 220 and a base plate 230. The dielectric plate 220 may be a disk-shaped dielectric substance. The substrate W is disposed on a top surface of the dielectric plate 220. According to an embodiment, the top surface of the dielectric plate 220 may have a diameter smaller than that of the substrate W. Accordingly, when the substrate W is placed on the top surface of the dielectric plate 220, an edge region of the substrate W may be positioned outside the dielectric plate 220.

The electrostatic electrode 222 is disposed within the dielectric plate 220. The electrostatic electrode 222 is electrically connected to a power source not shown. According to an embodiment, the power source (not shown) may be a DC power source. An electrostatic force is applied between the electrostatic electrode 222 and the substrate W by a direct current flowing through the electrostatic electrode 222. Accordingly, the substrate W is adsorbed to the dielectric plate 220. In addition, a heater (not shown) for adjusting a temperature of the dielectric plate 220 may be further disposed within the dielectric plate 220. If the heater (not shown) is disposed within the dielectric plate 220, the heater (not shown) may be disposed below the electrostatic electrode 222.

At least one first fluid channel 224 may be formed within the dielectric plate 220. The first fluid channel 224 may be formed from the top surface of the dielectric plate 220 to the bottom surface of the dielectric plate 220. The first fluid channel 224 may be connected to a second fluid channel 234 to be described later. The first fluid channel 224 functions as a passage through which a heat transfer medium to be described later is supplied to the bottom surface of the substrate W.

The base plate 230 is positioned below the dielectric plate 220. According to an embodiment, the base plate 230 may have a disk shape. A top surface of the base plate 230 may be stepped so that a central region thereof is positioned higher than an edge region. A top center region of the base plate 230 may have an area corresponding to the bottom surface of the dielectric plate 220. A central region of the top surface of the base plate 230 may be adhered to the bottom surface of the dielectric plate 220. A ring member 240 to be described later may be positioned above the edge region of the base plate 230.

The base plate 230 may be made of a conductive material. According to an embodiment, the base plate 230 may be a metal plate. For example, the material of the base plate 230 may include an aluminum. For example, an entire region of the base plate 230 may be made of a metal material.

The base plate 230 may be grounded. The base plate 230 may be grounded and function as a bottom electrode of a plasma source to be described later. However, the inventive concept is not limited to this, and the base plate 230 can be electrically connected to a high-frequency power source (not shown) which applies a high-frequency power. In addition, the base plate 230 may be electrically connected to a power source (not shown) for applying a bias power. However, hereinafter, for convenience of understanding, a case at which the base plate 230 is grounded will be described as an example.

A first circulation fluid channel 232, a second circulation fluid channel 234, and a second circulation fluid channel 236 may be positioned within the base plate 230.

The first circulation fluid channel 232 may be a passage through which the heat transfer medium circulates. The heat transfer medium may include an inert gas. For example, the heat transfer medium may include a helium gas. While performing a plasma treatment on the substrate W, the heat transfer medium may be a gas supplied to the bottom of the substrate W to eliminate a temperature imbalance of the substrate W. In the above-described example, the heat transfer medium has been described as a gas, but it may be a fluid.

The first circulation fluid channel 232 may have a spiral shape. However, the inventive concept is not limited thereto, and the first circulation fluid channel 232 may share a same center, but may be provided in a ring shape having a different radius. The first circulation fluid channel 232 connects to the second circulation fluid channel 234 to be described later.

The second fluid channel 234 connects to the first circulation fluid channel 232. In addition, the second fluid channel 234 connects to the first fluid channel 224. That is, the second fluid channel 234 fluidly communicates the first circulation fluid channel 232 with the first fluid channel 224. The heat transfer medium is supplied to the bottom of the substrate W through the first circulation fluid channel 232, the second fluid channel 234, and the first fluid channel 224.

The second circulation fluid channel 236 may be a passage through which a cooling fluid circulates. The cooling fluid may adjust a temperature of the base plate 230 while flowing within the second circulation fluid channel 236. Accordingly, a temperature of the substrate W may be adjusted via the base plate 230. The second circulation fluid channel 236 may be disposed below the first circulation fluid channel 232. The second circulation fluid channel 236 may have the same or similar shape as the first circulation fluid channel 232 described above. Accordingly, a detailed description of a shape of the second circulation fluid channel 236 will be omitted.

The ring member 240 is disposed in an edge region of the electrostatic chuck 210. According to an embodiment, the ring member 240 may be a focus ring. The ring member 240 generally has a ring shape. The ring member 240 is disposed along a circumference of the dielectric plate 220. In addition, the ring member 240 may be disposed above an edge region of the dielectric plate 220.

A top surface of the ring member 240 may be formed to be stepped. For example, an inner portion of the top surface of the ring member 240 may be positioned at a lower height than an outer portion of the top surface. According to an embodiment, the inner portion of the top surface of the ring member 240 may be positioned at the same height as the top surface of the dielectric plate 220. In addition, the inner portion of the top surface of the ring member 240 can support the bottom surface of the edge region of the substrate W positioned outside the dielectric plate 220. An outer portion of the top surface of the ring member 240 may surround the side surface of the substrate W.

An insulating plate 250 is positioned below the base plate 230. The insulating plate 250 may be made of an insulating material. The insulating plate 250 may have a substantially disk shape when viewed from above. In addition, the insulating plate 250 may have an area corresponding to that of the base plate 230.

The exhaust baffle 300 is positioned in the treating space 101. The exhaust baffle 300 is positioned above the exhaust hole 110. In addition, when viewed from above, the exhaust baffle 300 is positioned to overlap the exhaust hole 110. In addition, the exhaust baffle 300 is positioned between the inner sidewall of the chamber 100 and the support unit 200. The exhaust baffle 300 may have a substantially ring shape. At least one baffle hole 310 is formed in the exhaust baffle 300. The baffle hole 310 may be a through hole penetrating a top surface and a bottom surface of the exhaust baffle 300. A gas supplied to the treating space 101 and foreign substances generated in a process of treating the substrate W with the plasma are discharged to the exhaust hole 110 through the baffle hole 310.

The gas supply unit 400 supplies the gas to the treating space 101. The gas supplied to the treating space 101 may be a gas excited by the plasma. In addition, the gas supplied to the treating space 101 may be a gas contributing to ignition. In addition, the gas supplied to the treating space 101 may be a carrier gas.

The gas supply unit 400 may include a gas supply source 420, a gas supply line 440, and a valve 460. The gas supply source 420 stores the gas. An end of the gas supply line 440 may be connected to the gas supply source 420 and the other end thereof may be installed to communicate with the treating space 101. In FIG. 2, the other end of the gas supply line 440 is illustrated to communicate with the treating space 101 through the sidewall of the chamber 100, but is not limited thereto. For example, the other end of the gas supply line 440 may penetrate the window plate 500 to be described later and communicate with the treating space 101. The valve 460 is installed in the gas supply line 440. The valve 460 may be an opening/closing valve. In addition, the valve 460 may be a flow control valve.

The plasma source may include a top electrode and a bottom electrode. The top electrode and the bottom electrode are disposed to face each other. A high frequency power may be applied to any one of the two electrodes, and the other electrode may be grounded. Alternatively, the high frequency power may be applied to both electrodes. In addition, the high-frequency power may be applied to one of the two electrodes, and a bias power may be applied to the other electrode. An electric field is formed in a space between the two electrodes, and the gas supplied to the space may be excited in a plasma state. According to an embodiment, the top electrode may be an electrode unit 600 to be described later, and the bottom electrode may be the base plate 230 described above.

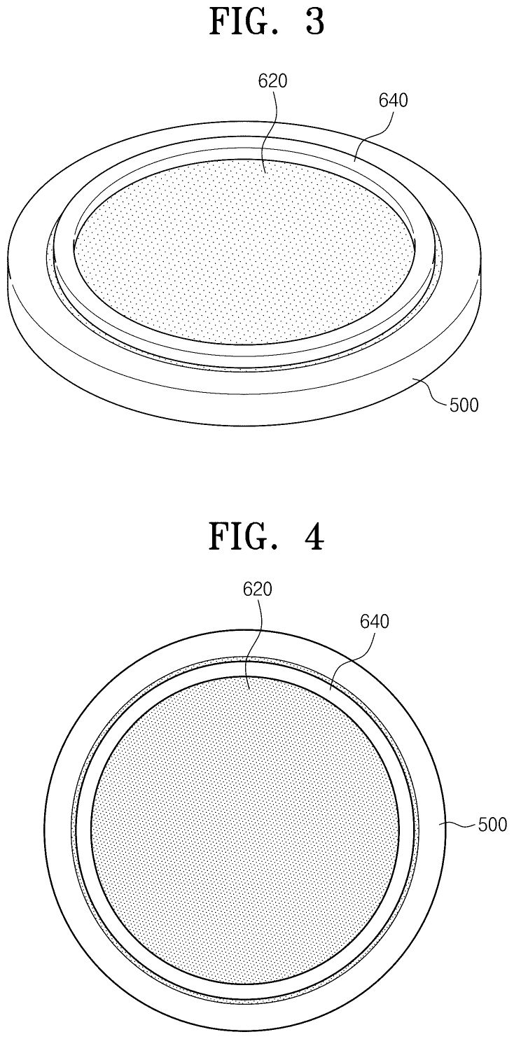

FIG. 3 is a perspective view schematically illustrating the window plate and the electrode according to an embodiment. FIG. 4 schematically illustrates the window plate and the electrode viewed from above according to an embodiment.

Hereinafter, the window plate and the top electrode according to an embodiment will be described with reference to FIG. 2 to FIG. 4.

The window plate 500 is positioned above the treating space 101. More specifically, the window plate 500 is combined with the chamber 100 to define the treating space 101. That is, by the window plate 500, the treating space 101 in a bottom side is defined, and the outer space in a top side is defined. Accordingly, a bottom surface of the window plate 500 is exposed to the treating space 101. Alternatively, a top surface of the window plate 500 is not exposed to the treating space 101.

The window plate 500 may have a substantially circular shape when viewed from above. However, the inventive concept is not limited thereto, and a cross-sectional shape of the window plate 500 may be variously changed. The window plate 500 may be an insulation window. The window plate 500 may be made of a material capable of transmitting a wavelength. In addition, the window plate 500 may be made of a material having a corrosion resistance. According to an embodiment, the material of the window plate 500 may include a quartz.

The electrode unit 600 is positioned above the window plate 500. More specifically, the electrode unit 600 is positioned in an outer space. As described above, the electrode unit 600 may function as a top electrode among plasma sources. The electrode unit 600 may include a conductive layer 620, an electrode 640, a high frequency power source 660, and an impedance matcher 680.

The conductive layer 620 according to an embodiment may be provided as a film including a metal material having a good conductivity. In this case, the conductive layer 620 may be made of a material including a Cu, an Al, or an Ag. However, the material forming the conductive layer 620 is not limited to the above-described example, and may further include a known metal having a good conductivity.

The conductive layer 620 is formed on a top surface the top surface and the bottom surface of the window plate 500. More specifically, the conductive layer 620 may be coated on the top surface of the window plate 500. The conductive layer 620 is positioned in the outer space described above. That is, the conductive layer 620 may not be exposed to the treating space 101. For example, the conductive layer 620 may be coated on the window plate 500 by a method such as a chemical vapor deposition (CVD) or a physical vapor deposition (PVD).

The conductive layer 620 is coated along a circumference of the window plate 500. More specifically, the conductive layer 620 is coated along a circumference of an edge region of the window plate 500. The conductive layer 620 coated on the window plate 500 may have a substantially circular shape when viewed from above. However, the inventive concept is not limited thereto, and the conductive layer 620 may be coated on the window plate 500 to have various shapes. In addition, the conductive layer 620 may overlap the substrate W positioned in the treating space 101 when viewed from above.

The electrode 640 is positioned above the window plate 500. In addition, the electrode 640 is disposed above the conductive layer 620. The electrode 640 may be bonded to the conductive layer 620. More specifically, a bottom surface of the electrode 640 and a top surface of the conductive layer 620 may be bonded by an ohmic contact. Accordingly, a contact resistance that may occur between the electrode 640 and the conductive layer 620 may be minimized.

The electrode 640 may have a substantially ring shape. In the drawing according to an embodiment, a cross-section of the electrode 640 is generally shown to be rectangular, but the shape of the electrode 640 may be variously modified. The electrode 640 is disposed within a region coated with the conductive layer 620 when viewed from above. More preferably, the electrode 640 is disposed along a circumference of an edge region of the conductive layer 620. In addition, the electrode 640 may partially overlap the edge region of the substrate W positioned in the treating space 101. In addition, a material of the electrode 640 may include a metal having an excellent conductivity. The metal according to an embodiment may include a copper Cu or an aluminum Al.

The electrode 640 connects to the high frequency power source 660. According to an embodiment, the electrode 640 may be electrically connected to the high-frequency power source 660 via a metal strip or a bar. The high frequency power supply 660 applies a high frequency voltage to the electrode 640. An impedance matcher 680 may be installed between the high frequency power source 660 and the electrode 640. The impedance matcher 680 matches the impedance of high frequency power applied to the electrode 640. In addition, an electrode switch (not shown) is installed between the high-frequency power source 660 and the electrode 640. If the electrode switch (not shown) is turned on, the high-frequency power is applied to the electrode 640, and the high-frequency power applied to the electrode 640 can be conducted along a lengthwise direction of the electrode 640.

As described above, since the material of the electrode 640 includes a copper Cu or an aluminum Al with an excellent conductivity, the high-frequency power applied from the high-frequency power source 660 can be efficiently conducted within the ring-shaped electrode 640. In addition, as described above, since the conductive layer 620 and the electrode 640 are bonded to each other in an ohmic contact manner, the high-frequency power conducted to the electrode 640 can be conducted to the conductive layer 620 with minimal contact resistance. Accordingly, the conductive layer 620 and the electrode 640 are combined with each other to function as a top electrode among the plasma sources. If the high-frequency power is applied to the top electrode, an electric field is formed between the top electrode and a base plate 230 that serves as an opposite electrode of the top electrode. That is, the electric field is formed in the treating space 101. The electric field formed in the treating space 101 excites the gas supplied from the above-described gas supply unit 400. That is, the plasma is generated in the treating space 101, and the plasma may act with the substrate W to treat the substrate W.

As described above, the conductive layer 620 is positioned outside the treating space 101. Since the treating space 101 according to an embodiment functions as a space at which the plasma is generated, if the conductive layer 620 is exposed to the treating space 101, the conductive layer 620 may be damaged by the plasma. In addition, since the conductive layer 620 functions as one of the top electrodes, it is difficult to generate a uniform plasma in the treating space 101 if the conductive layer 620 is damaged. Accordingly, according to the above-described embodiment, it is possible to form a uniform plasma in the treating space 101 by minimizing a possibility that the conductive layer 620 is damaged by plasma.

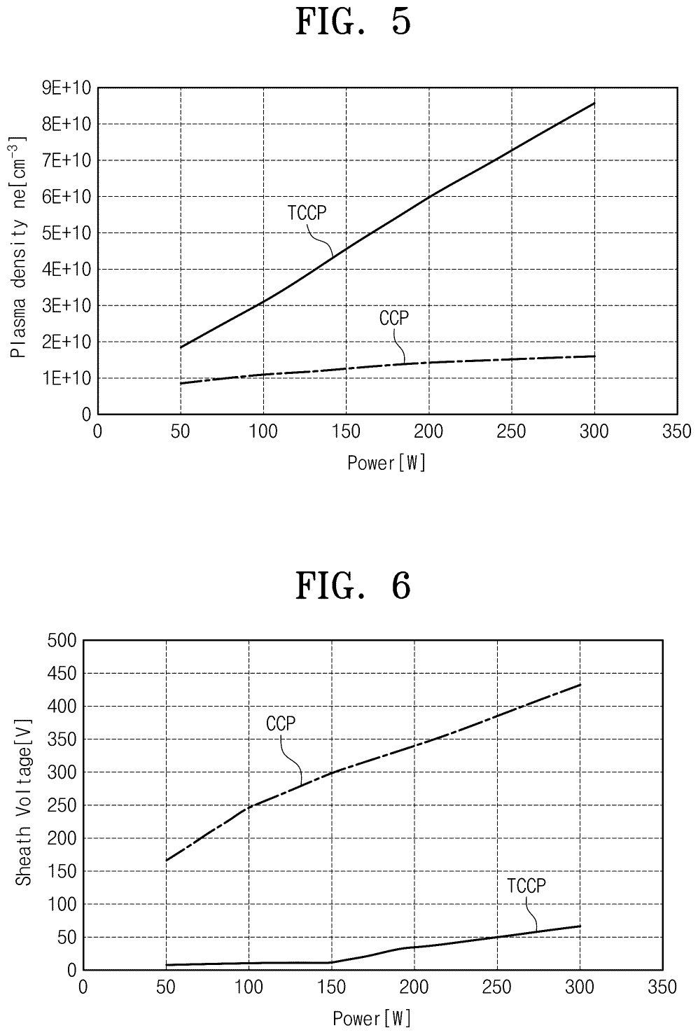

FIG. 5 is a graph schematically illustrating a trend of a sheath voltage in the substrate treating apparatus according to an embodiment. FIG. 6 is a graph schematically illustrating a trend of density of the plasma generated in the substrate treating apparatus according to an embodiment.

As described above, since the window plate 500 may be made of a quartz material, the high-frequency power conducted to the conductive layer 620 drops a voltage in a process of passing through an inside of the window plate 500. Accordingly, a sheath application voltage of the treating space 101 is significantly lowered. For example, as described in FIG. 6, the sheath voltage due to a voltage drop in the substrate treating apparatus 10 (TCCP) according to an embodiment may be approximately 7 to 30 times lower than the sheath voltage in a general substrate treating apparatus (CCP). Due to the sheath voltage lowered in the treating space 101, an etching of the window plate 500 by the plasma may be minimized. Accordingly, it is possible to minimize an attachment of foreign substances which may be generated by etching the window plate 500 to the substrate W.

In addition, as described in FIG. 6, a plasma density of the plasma generated by the substrate treating apparatus 10 (TCCP) according to an embodiment may be approximately three to four times higher than the plasma density of the plasma generated by the general substrate treating apparatus (CCP). This is the result of ions by a lowered sheath voltage. That is, an energy required for a plasma generation is minimized, thereby improving a plasma generation efficiency, thereby generating a high-density plasma.

In addition, since the electrode 640 according to an embodiment has a ring shape, a uniform plasma may be generated in the treating space 101. In addition, the conductive layer 620 may be formed to overlap the substrate W positioned in the treating space 101 when viewed from above as described above. Since the conductive layer 620 functions as the top electrode, the plasma that may act on an entire region of the substrate W may be uniformly generated.

Hereinafter, the substrate treating apparatus according to another embodiment will be described. The substrate treating apparatus described below and the components included therein are mostly the same as or similar to the embodiment described with reference to FIG. 2 to FIG. 6 in addition to the case of additional description. Accordingly, the description of the overlapping content will be omitted below.

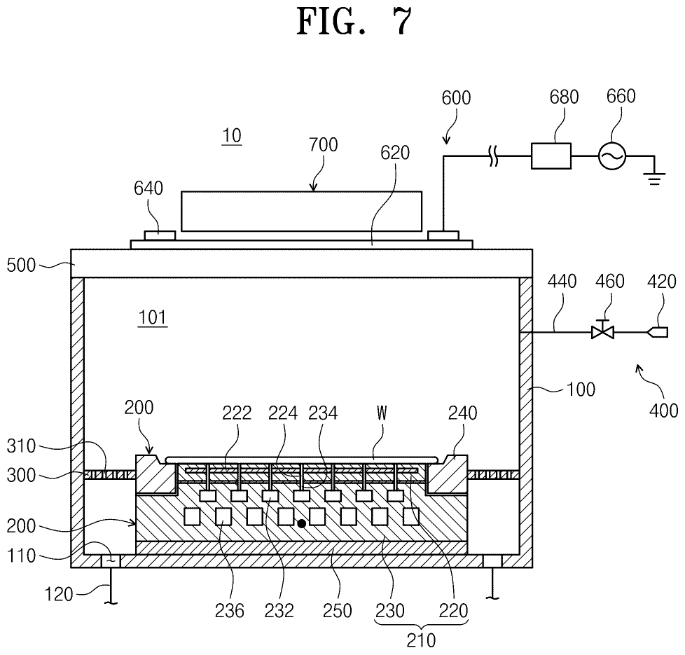

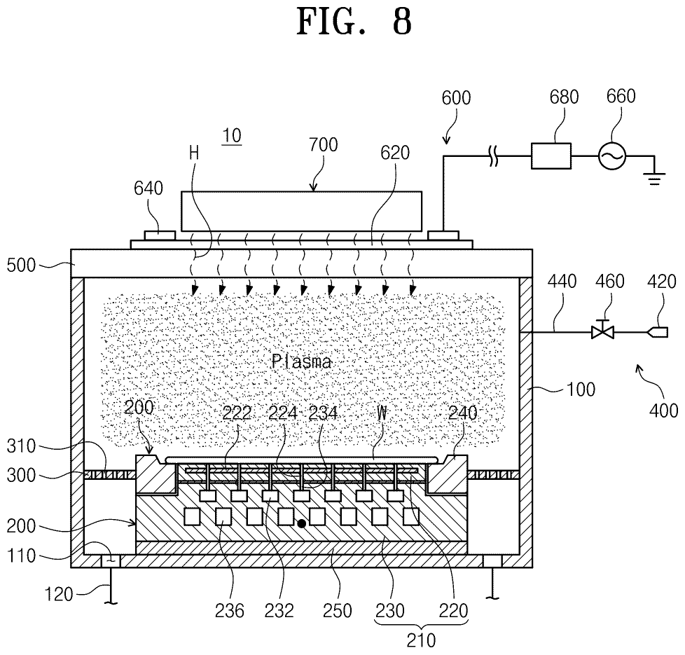

FIG. 7 is a cross-sectional view schematically illustrating the substrate treating apparatus according to another embodiment. FIG. 8 schematically illustrates the substrate being treated in the substrate treating apparatus of FIG. 7.

The conductive layer 620 according to an embodiment may be a transparent conductive oxide. The transparent conductive oxide according to an embodiment may be an indium tin oxide (ITO). In addition, the transparent conductive oxide may be any one of an AZO, an FTO, an ATO, an SnO₂, a ZnO, an IrO₂, a graphene, a metal nanowire, or a CNT, or a mixture of one or more of these materials, or a multiple overlapping. However, the inventive concept is not limited to the above-mentioned example, and the conductive layer 620 according to an embodiment may be made of a material capable of transmitting a heat source H provided by the heating unit 700 to be described later.

The substrate treating apparatus 10 may further include a heating unit 700. The heating unit 700 transfers the heat source H to the substrate W supported by the support unit 200. The heating unit 700 may include a lamp, a laser optical system, or a microwave generator. For example, the lamp may include a flash lamp or an IR lamp. If the heating unit 700 is a lamp, the heating unit 700 transfers a light, which is a heat source H, to the substrate W. In addition, if the heating unit 700 is a laser optical system, the heating unit 700 transmits a laser, which is a heat source H, to the substrate W. In addition, if the heating unit 700 is a microwave generator, the heating unit 700 may consist of a waveguide which applies microwaves and an antenna. In addition, if the heating unit 700 is a microwave generator, the heating unit 700 transmits microwaves, which are heat sources H, to the substrate W.

The heating unit 700 is positioned above the window plate 500 and the conductive layer 620. In addition, the heating unit 700 is arranged so that the heat source H passes through the conductive layer 620. As described above, the conductive layer 620 is coated on the top surface of the window plate 500 to have a predetermined thickness. The predetermined thickness may be a thickness through which the heat source H transferred from the heating unit 700 may pass through. In addition, the thickness of the conductive layer 620 coated on the top surface of the window plate 500 can be applied differently depending on the type of heat source H transmitted by the heating unit 700. In addition, the material of the conductive layer 620 may be selected differently depending on the type of heat source H transmitted by the heating unit 700.

The heat source H is transferred to the window plate 500 through the conductive layer 620. As described above, the window plate 500 may be made of a material capable of transmitting waves, so the transferred heat source H is transmitted through the window plate 500 and transmitted to the treating space 101. The heat source H transferred to the treating space 101 is transferred to the substrate W.

According to an embodiment of the inventive concept, a processing efficiency of the substrate W can be further improved when performing an atomic layer etching (ALE) process to etch an atomic layer on the substrate W or a process which needs to increase a temperature on the substrate W. More specifically, since the heat source H is efficiently transferred to the substrate W through the conductive layer 620 and the window plate 500, the substrate W can be treated more efficiently in a process that requires heating of the substrate W.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a chamber having a treating space;
a support unit configured to support a substrate in the treating space;
a window plate positioned above the treating space; and
a conductive layer formed on the window plate, and
wherein a bottom surface of the window plate is exposed to the treating space, and
the conductive layer is formed on a top surface among a top surface and a bottom surface of the window plate.

2. The substrate treating apparatus of claim 1, wherein the conductive layer is coated to have a predetermined thickness on the top surface of the window plate.

3. The substrate treating apparatus of claim 2, wherein an electrode in a ring shape to which a high-frequency voltage is applied is disposed above the conductive layer.

4. The substrate treating apparatus of claim 3, wherein the electrode is positioned within a coated region of the conductive layer when seen from above.

5. The substrate treating apparatus of claim 4, wherein the electrode is disposed along a circumference of an edge region of the conductive layer.

6. The substrate treating apparatus of claim 4, wherein the electrode partially overlaps a substrate supported on the support unit when seen from above.

7. The substrate treating apparatus of claim 4, wherein a bottom surface of the electrode and a top surface of the conductive layer are bonded to each other by an ohmic contact.

8. The substrate treating apparatus of claim 3, wherein a material of the window plate includes a quartz,
a material of the electrode includes a metal, and
the metal includes a copper (Cu) or an aluminum (Al).

9. The substrate treating apparatus of claim 2, wherein the conductive layer is provided as a transparent conductive layer, and the transparent conductive layer is made of a material including an ITO (Indium tin oxide).

10. The substrate treating apparatus of claim 9 further comprising:
a heating unit configured to transfer a heat source to a substrate supported on the support unit, and
wherein the heating unit is positioned at a top side of the transparent conductive layer.

11. The substrate treating apparatus of claim 10, wherein the heating unit transfers the heat source to the treating space by passing through the transparent conductive layer.

12. The substrate treating apparatus of claim 11, wherein the heating unit includes a lamp, a laser optical system, or a microwave generator.

13. A substrate treating apparatus comprising:
a window plate dividing into an outer space at a top side and a treating space at a bottom side;
an electrode positioned at the outer space and forming an electric field at the treating space by applying a power;
a heating unit positioned at the outer space and configured to transfer a heat source to the treating space; and
a transparent conductive layer positioned at the outer space among the treating space and the outer space.

14. The substrate treating apparatus of claim 13, wherein the electrode is disposed along a circumference of an edge region of the transparent conductive layer.

15. The substrate treating apparatus of claim 14, wherein the electrode is positioned above the edge region of the transparent conductive layer.

16. The substrate treating apparatus of claim 15, wherein the transparent conductive layer is formed at a top surface of the window plate, and
the heating unit transfers the heat source toward the transparent conductive layer.

17. The substrate treating apparatus of claim 16, wherein the electrode partially overlaps with a substrate positioned at the treating space when seen from above.

18. The substrate treating apparatus of claim 15, wherein a bottom surface of the electrode and a top surface of the transparent conductive layer are bonded to each other by an ohmic contact.

19. The substrate treating apparatus of claim 14, wherein a material of the window plate includes a quartz,
a material of the electrode includes a copper (Cu) or an aluminum (Au), and
the transparent conductive layer is made of material including an ITO (Indium tin oxide).

20. A substrate treating apparatus comprising:
a chamber having a treating space;
a support unit configured to support a substrate in the treating space;
a gas supply unit configured to supply a gas to the treating space;
an electrode positioned outside of the treating space, and exciting a gas supplied to the treating space by applying a high-frequency voltage;
a heating unit positioned outside of the treating space and configured to transmit a heat source to the treating space;
a window plate with its bottom surface exposed to the treating space and its top surface positioned outside of the treating space; and
a transparent conductive layer formed on the top surface of the window plate, and
wherein a top surface of the transparent conductive layer and a bottom surface of the electrode contact each other,
the heating unit is positioned at a top side of the transparent conductive layer,
the electrode is positioned at an edge region of the transparent conductive layer along a circumferential direction of the transparent conductive layer,
the heating unit transmits the heat source to the treating space by passing through the transparent conductive layer,
a material of the electrode includes a copper (Cu) or an aluminum (Al), and
the transparent conductive layer is made of a material including an ITO (Indium tin oxide).
